(19) United States
(12) Patent Application Publication
(10) Pub. No.: US 2014/0004636 A1
(43) Pub. Date: Jan. 2, 2014

(54) METHOD OF MANUFACTURING AN LED

(71) Applicant: NITTO DENKO CORPORATION, Osaka (JP)

(72) Inventors: Tomokazu TAKAHASHI, Ibaraki-shi (JP); Shinya AKIZUKI, Ibaraki-shi (JP); Toshimasa SUGIMURA, Ibaraki-shi (JP); Takeshi MATSUMURA, Ibaraki-shi (JP); Daisuke UENDA, Ibaraki-shi (JP)

(21) Appl. No.: 13/917,135

(22) Filed: Jun. 13, 2013

(30) Foreign Application Priority Data
Jun. 28, 2012 (JP) 2012-145448

(51) Int. Cl. H01L 33/60

(52) U.S. Cl. CPC H01L 33/60
USPC 438/29

(57) ABSTRACT

A method of manufacturing an LED including: back-grinding a substrate of an LED wafer including a light emitting element and the substrate; and attaching a protective sheet to the LED wafer one of prior to the back-grinding and after grinding the substrate in the back-grinding.

This application claims priority under 35 U.S.C. Section 119 to Japanese Patent Application No. 2012-145448 filed on Jun. 28, 2012, which are herein incorporated by references.

### BACKGROUND OF THE INVENTION

1. Field of the Invention

The present invention relates to a method of manufacturing an LED.

2. Description of the Related Art

Hitherto, in manufacture of an LED, a light emitting element is laminated on a substrate to form an LED wafer, and then a surface of the substrate on a side opposite to the light emitting element is ground (back-ground) to thin the substrate (for example, Japanese Patent Application Laid-open Nos. 2005-150675 and 2002-319708). Generally, this grinding is carried out while fixing a surface of the substrate on the light emitting element side to a table via a pressure-sensitive adhesive wax. The LED wafer that has undergone grinding is subjected to, for example, steps of heating the wax to release the LED wafer, cleaning the wax adhering on the LED wafer, cutting (dicing) the LED wafer to singulate small element pieces, and forming a reflective layer on the surface of the substrate on the side opposite to the light emitting element. The LED wafer that has undergone the back-grinding step is very thin, and hence there is a problem in that, in those steps of the post-process, damage such as cracking easily occurs.

### SUMMARY OF THE INVENTION

The present invention has been made to solve the above-mentioned conventional problem, and has an object to provide a method of manufacturing an LED, which is capable of manufacturing an LED with high yields by preventing damage to the LED wafer.

A method of manufacturing an LED according to an embodiment of the present invention includes:
back-grinding a substrate of an LED wafer including a light emitting element and the substrate; and
attaching a protective sheet to the LED wafer one of prior to the back-grinding and after grinding the substrate in the back-grinding.

In an embodiment of the present invention, the attaching a protective sheet includes, prior to the back-grinding, attaching the protective sheet on an outer side of the light emitting element of the LED wafer.

In an embodiment of the present invention, the grinding the substrate in the back-grinding is carried out by attaching the protective sheet to a table via a pressure-sensitive adhesive wax to fix the LED wafer to the table, and the method further comprises, after the grinding the substrate, taking off the protective sheet to remove, from the LED wafer, the pressure-sensitive adhesive wax adhering on the LED wafer with the protective sheet, which has been released from the table.

In an embodiment of the present invention, the attaching a protective sheet includes, after the grinding the substrate in the back-grinding, attaching the protective sheet on an outer side of the substrate of the LED wafer.

In an embodiment of the present invention, the method further includes, after the back-grinding, forming a reflective layer.

According to the present invention, the protective sheet is attached to the LED wafer, and thus the damage to the LED wafer may be prevented to manufacture the LED with high yields.

### BRIEF DESCRIPTION OF THE DRAWINGS

In the accompanying drawings:

FIGS. 1A to 1D are schematic views illustrating respective steps of a method of manufacturing an LED according to an embodiment of the present invention;

FIG. 2 is a schematic sectional view of an LED wafer used in the method of manufacturing an LED according to the embodiment of the present invention;

FIGS. 3A to 3D are schematic views illustrating respective steps of a method of manufacturing an LED according to another embodiment of the present invention;

FIGS. 4A to 4F are schematic views illustrating respective steps after a back-grinding step in a method of manufacturing an LED according to still another embodiment of the present invention;

FIGS. 5A to 5F are schematic views illustrating respective steps after a back-grinding step in a method of manufacturing an LED according to further another embodiment of the present invention; and

FIGS. 6A to 6F are schematic views illustrating respective steps after a back-grinding step in a method of manufacturing an LED according to yet another embodiment of the present invention.

### DETAILED DESCRIPTION OF THE PREFERRED EMBODIMENTS

A method of manufacturing an LED according to the present invention includes attaching a protective sheet to an LED wafer including a light emitting element and a substrate. In the present invention, the protective sheet may be attached to the LED wafer prior to a back-grinding step (first embodiment), or the protective sheet maybe attached to the LED wafer after the substrate is ground in the back-grinding step (second embodiment). In the present invention, the LED wafer is protected by the protective sheet, and thus during the back-grinding step, steps after the back-grinding step, and handling between the steps, the damage (for example, cracking) to the LED wafer can be prevented.

### A. First Embodiment

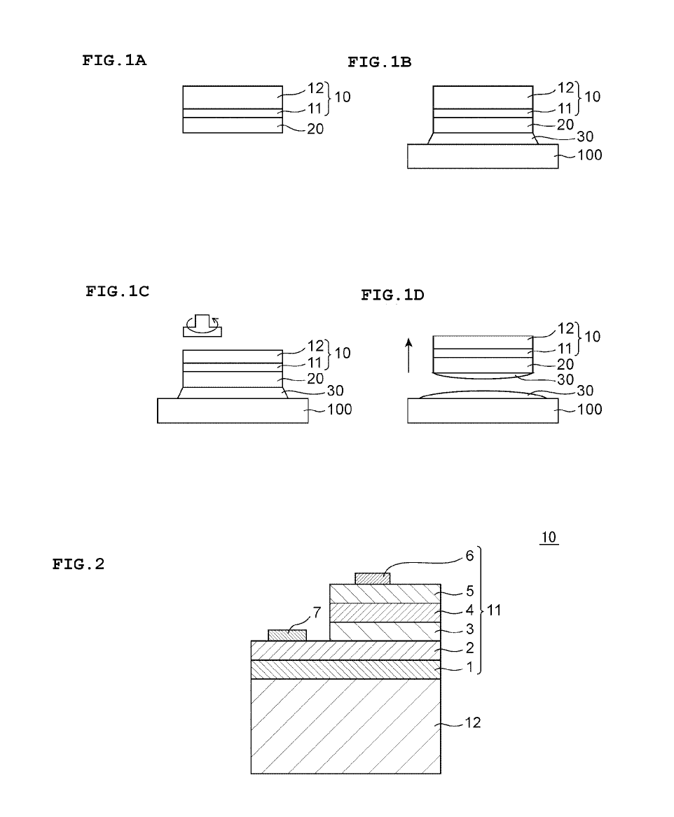

FIGS. 1A to 1D are schematic views illustrating respective steps of a method of manufacturing an LED according to an embodiment of the present invention. Further, FIG. 2 is a schematic sectional view of an LED wafer 10. The LED wafer 10 includes a light emitting element 11 and a substrate 12. The light emitting element 11 includes a buffer layer 1, an n-type semiconductor layer 2, a light emitting layer 3, a p-type semiconductor layer 4, a transparent electrode 5, and electrodes 6 and 7. The light emitting layer 3 includes, for example, gallium nitride-based compounds (e.g., GaN, AlGaN, and InGaN), gallium phosphide-based compounds (e.g., GaP and GaAsP), gallium arsenide-based compounds (e.g., GaAs, AlGaAs, and AlGaInP), and zinc oxide (ZnO)-based compounds. Note that, although not illustrated, the light emitting element 11 may include any other appropriate members. The substrate 12 is made of any appropriate material. Examples of the material for constituting the substrate 12 include sapphire, SiC, GaAs, GaN, and GaP. The effects of the present invention are markedly obtained when the employed LED wafer 10 is made of such a hard and brittle material as those materials.

In this embodiment, first, as illustrated in FIG. 1A, prior to the back-grinding step, a protective sheet 20 is attached onto an outer side of the light emitting element 11 of the LED wafer 10. After that, the LED wafer with the protective sheet is subjected to the back-grinding step (FIGS. 1B to 1D).

As the protective sheet 20, any appropriate sheet may be used. A representative protective sheet includes a base member and a pressure-sensitive adhesive layer. As a material for constituting the base member, there may be given, for example: polyolefins such as polyethylene, polypropylene, polybutene, polybutadiene, and polymethylpentene; and polyvinyl chloride, a polyvinyl chloride copolymer, polyethylene terephthalate, polybutylene terephthalate, polyurethane, an ethylene-vinyl acetate copolymer, an ethylene-(meth)acrylic acid copolymer, an ethylene-(meth)acrylate ester copolymer, polystyrene, polycarbonate, polyimide, and a fluorine-based resin. As a form of the base member, there may be given, for example, film, woven fabric, and non-woven fabric. In addition, the base member may be paper or a metal foil. As a material for constituting the pressure-sensitive adhesive layer, there may be given, for example, a rubber-based resin, an acrylic resin, a silicone-based resin, and a polyimide-based resin.

In the back-grinding step, the LED wafer with the protective sheet is fixed on a table 100. The LED wafer with the protective sheet is fixed, for example, as illustrated in FIG. 1B, by attaching the protective sheet 20 to the table 100 via a pressure-sensitive adhesive wax 30. As the pressure-sensitive adhesive wax 30, any appropriate wax may be used as long as the LED wafer 10 may be satisfactorily fixed. Examples of the pressure-sensitive adhesive wax 30 include paraffin-based wax. In the embodiment illustrated in FIGS. 1A to 1D, the LED wafer 10 and the pressure-sensitive adhesive wax 30 are not brought into contact with each other, and hence the LED wafer 10 can be prevented from being stained.

After the LED wafer 10 is fixed as described above, as illustrated in FIG. 1C, a surface of the LED wafer 10 on a side opposite to the light emitting element 11 (that is, the substrate 12) is ground. With this grinding, the substrate 12 can be thinned to a desired thickness. The thickness of the substrate 12 that has undergone grinding is preferably 10 μm to 500 μm, more preferably 50 μm to 300 μm, most preferably 80 μm to 150 μm. Further, the diameter of the employed LED wafer 10 is preferably 2 inches or more, more preferably 3 inches or more, most preferably 4 inches or more. The upper limit of the diameter of the LED wafer 10 is not particularly limited, but in practical use, the diameter is about 12 inches, for example. In the embodiment illustrated in FIGS. 1A to 1D, the LED wafer 10 is protected by the protective sheet 20, and hence the LED wafer 10 may be prevented from being damaged during grinding. Further, the LED wafer 10 can be prevented from being damaged as described above, and hence a large-size (for example, 4 inches or more) LED wafer larger than the conventional one can be handled, and hence the LED can be manufactured with high yields.

After the substrate 12 is ground as described above, as illustrated in FIG. 1D, the LED wafer with the protective sheet is released from the table 100. For example, heating is performed until the pressure-sensitive adhesive wax 30 exhibits flowability, and thus the LED wafer with the protective sheet is released from the table 100. In the embodiment illustrated in FIGS. 1A to 1D, the LED wafer 10 is protected by the protective sheet 20, and hence the LED wafer 10 may be prevented from being damaged when the LED wafer 10 is released from the table 100.

In the embodiment illustrated in FIGS. 1A to 1D, it is unnecessary to perform a step of cleaning the pressure-sensitive adhesive wax 30, which has been conventionally necessary after the back-grinding step. This is because, by peeling off the protective sheet 20 from the LED wafer 10, the pressure-sensitive adhesive wax 30 can also be removed together with the protective sheet 20. The step of cleaning the pressure-sensitive adhesive wax 30 can be omitted, and hence the use of cleaning liquid such as a solvent can be avoided. Thus, an LED can be simply manufactured with a small environmental load. Further, an adverse effect to the LED due to the cleaning liquid can be prevented.

### B. Second Embodiment

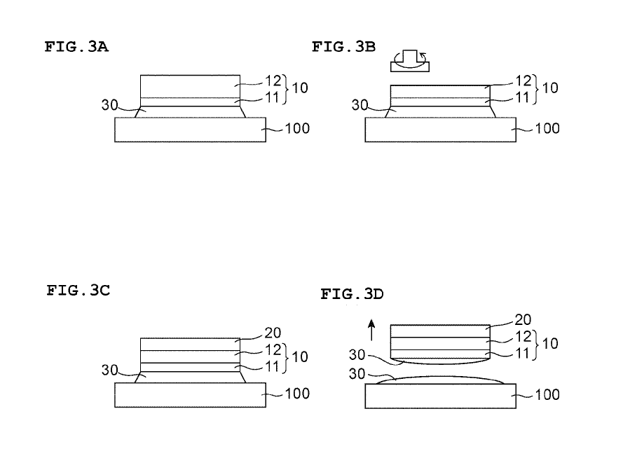

FIGS. 3A to 3D are schematic views illustrating respective steps of a method of manufacturing an LED according to another embodiment of the present invention. In this embodiment, after the substrate is ground in the back-grinding step, the protective sheet is attached to the LED wafer. In this embodiment, as illustrated in FIG. 3A, the light emitting element 11 of the LED wafer 10 is attached to the table 100 via the pressure-sensitive adhesive wax 30, to thereby fix the LED wafer 10 onto the table 100. Subsequently, as illustrated in FIG. 3B, the surface of the LED wafer 10 on the side opposite to the light emitting element 11 (that is, the substrate 12) is ground, to thereby thin the substrate 12. Subsequently, as illustrated in FIG. 3C, the protective sheet 20 is attached to the surface of the LED wafer 10 on the side opposite to the light emitting element 11 (that is, on the outer side of the substrate 12). Subsequently, as illustrated in FIG. 3D, the LED wafer with the protective sheet is released from the table 100. Note that, although not illustrated, in this embodiment, after the LED wafer with the protective sheet is released from the table 100, the pressure-sensitive adhesive wax 30 is cleaned. The pressure-sensitive adhesive wax 30 can be cleaned by immersing the LED wafer with the protective sheet into an organic solvent which can dissolve the pressure-sensitive adhesive wax.

In the embodiment illustrated FIGS. 3A to 3D, the LED wafer 10 is protected by the protective sheet 20, and hence the LED wafer 10 may be prevented from being damaged when the LED wafer 10 is released from the table 100 and handled thereafter.

### C. Other Steps (Steps after Back-Grinding Step)

The LED wafer 10 that has undergone the back-grinding step, in which the substrate 12 has been ground as described above, is subjected to steps of the post-process including, for example, a step of cutting the LED wafer 10 to singulate small element pieces (dicing step), and a step of forming a reflective layer on the surface of the substrate on the side opposite to the light emitting element (reflective layer forming step). According to the manufacturing method of the present invention, the LED wafer 10 is protected by the protective sheet 20 to prevent damage during the respective steps and handling between the respective steps. Therefore, a large-size (for example, 4 inches or more) LED wafer larger than the conventional one can be handled, and hence the LED can be manufactured with high yields.

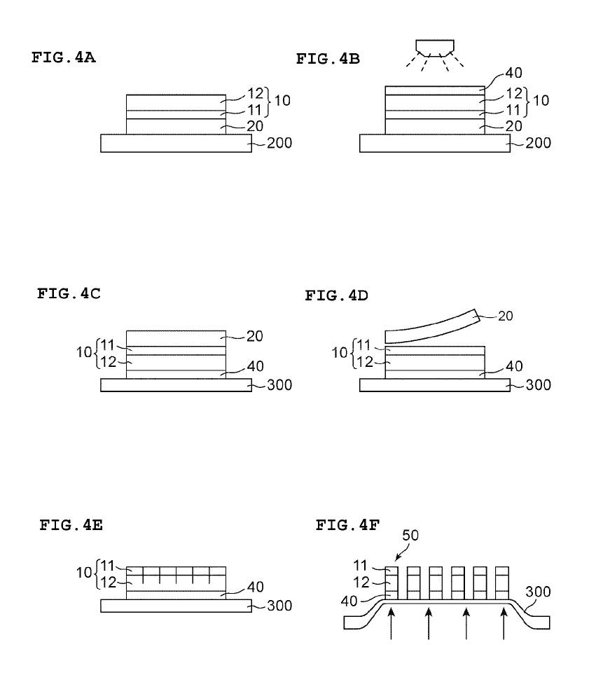

FIGS. 4A to 4F are schematic views illustrating respective steps in a method of manufacturing an LED according to still another embodiment of the present invention. FIGS. 4A to 4F illustrate steps subsequent to the back-grinding step for the LED wafer with the protective sheet, which is obtained through the above-mentioned first embodiment (embodiment illustrated in FIGS. 1A to 1D).

In this embodiment, as illustrated in FIGS. 4A and 4B, the LED wafer with the protective sheet, which has been subjected to the back-grinding step, is subjected to the reflective layer forming step. Specifically, the LED wafer with the protective sheet is placed on a table 200 with the protective sheet 20 side down (FIG. 4A). After that, a reflective layer 40 is formed on the LED wafer on a side opposite to the protective sheet (that is, the substrate 12 side) (FIG. 4B). By forming the reflective layer 40, the amount of light to be extracted from the light emitting element 11 can be increased. As a material for constituting the reflective layer 40, any appropriate material may be used as long as the light from the light emitting element 11 may be satisfactorily reflected. Examples of the material for constituting the reflective layer 40 include metals such as aluminum, silver, gold, palladium, platinum, rhodium, and ruthenium. The reflective layer 40 made of a metal maybe formed by, for example, a vapor deposition method (for example, a metal organic chemical vapor deposition method (MOCVD method)). It is preferred that an underlayer formed of, for example, SiO₂, TiO₂, ZrO₂, and/or MgF₂ be formed on the surface of the LED wafer 10 on the side opposite to the light emitting element 11, and then the reflective layer 40 made of a metal be formed by a vapor deposition method. For example, the LED wafer with the protective sheet (LED wafer with the protective sheet formed in the first embodiment) including the protective sheet 20 on the outer side of the light emitting element 11 of the LED wafer 10 is subjected to the reflective layer forming step, and thus the metal may be prevented from being deposited on the light emitting element 11.

After the reflective layer 40 is formed, as illustrated in FIGS. 4C to 4F, the LED wafer with the protective sheet, which has the reflective layer 40 formed thereon, is subjected to the dicing step. Specifically, the LED wafer with the protective sheet, which has the reflective layer 40 formed thereon, is retained on dicing tape 300 with the protective sheet 20 side up (FIG. 4C). After that, the protective sheet 20 is peeled off (FIG. 4D). Subsequently, the LED wafer 10 (substantially, the substrate 12) is half-cut in the thickness direction from the exposed light emitting element 11 side (FIG. 4E). After that, the dicing tape 300 is expanded so that the LED wafer 10 having the reflective layer 40 formed thereon is split from the cut portion as an origin to obtain LEDs 50 singulated into small element pieces (FIG. 4F).

Referring to FIGS. 4E and 4F, description has been made of the embodiment in which the LED wafer 10 is half-cut so as to split the LED wafer from the cut portion as the origin (scribe dicing). In FIG. 4E, the LED wafer 10 is half-cut from the light emitting element 11 side. However, the dicing tape 300 maybe alternatively attached with the substrate 12 (reflective layer 40) side up, and the LED wafer 10 may be half-cut from the substrate 12 side (reflective layer 40 side). Further, as a method of cutting the LED wafer, in addition to the above-mentioned scribe dicing, any appropriate method may be adopted. Examples of other methods include a method of cutting the LED wafer 10 in the entire thickness direction to singulate the small element pieces through expanding, and a method of laser cutting only the center portion of the LED wafer 10 in the thickness direction to split the LED wafer 10 from the cut portion as an origin (stealth dicing).

Referring to FIGS. 4A to 4F, description has been made of the embodiment in which the protective sheet 20 is not peeled off after the back-grinding step, and the LED wafer with the protective sheet is subjected to the post-process (in FIGS. 4A to 4F, the reflective layer forming step), but the LED wafer may be subjected to the post-process after the protective sheet 20 is peeled off. It is preferred that, as illustrated in FIGS. 4A to 4F, the LED wafer with the protective sheet be subjected to the post-process. This is because, also in the post-process, the thinned LED wafer can be protected, and the damage to the LED wafer can be prevented.

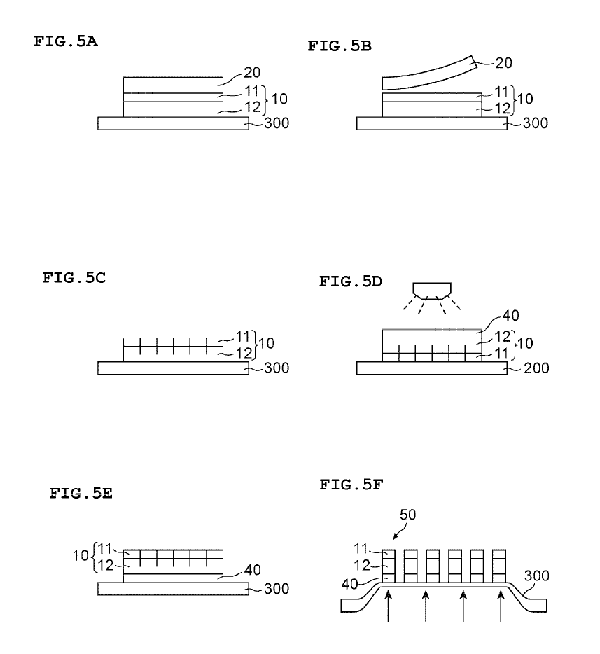

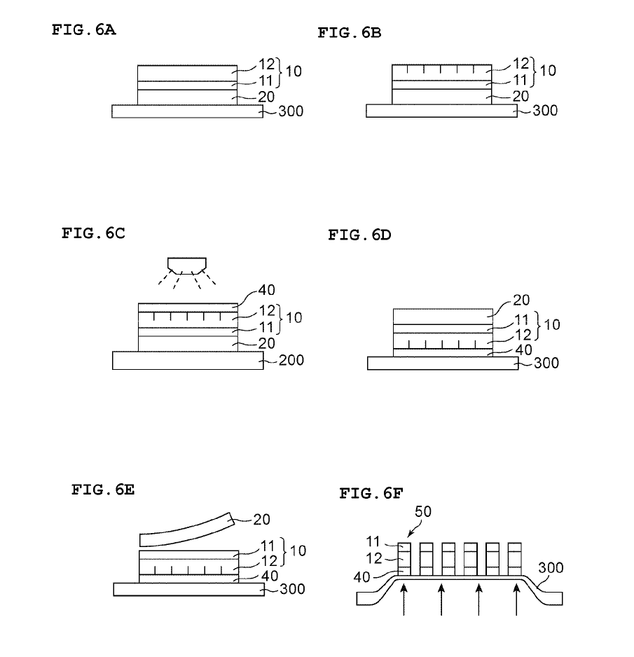

Referring to FIGS. 4A to 4F, description has been made of the embodiment in which, prior to the formation of the cut portion for splitting, the reflective layer forming step is performed. The reflective layer forming step may be performed prior to the formation of the cut portion as described above, or may be performed after the cut portion is formed as illustrated in FIGS. 5A to 5F and 6A to 6F. In an embodiment of the present invention illustrated in FIGS. 5A to 5F, the LED wafer with the protective sheet, which has been subjected to the back-grinding step, is retained on the dicing tape 300 with the protective sheet 20 side up (FIG. 5A), and after that, the protective sheet 20 is peeled off (FIG. 5B). Subsequently, the LED wafer 10 is half-cut from the exposed light emitting element 11 side (FIG. 5C). Subsequently, the LED wafer 10 having the cut portion formed therein as described above is subjected to the reflective layer forming step. That is, the LED wafer 10 is placed on the table 200 with the light emitting element 11 side down, and the reflective layer 40 is formed on the substrate 12 side of the LED wafer 10 (FIG. 5D). Subsequently, the LED wafer 10 having the reflective layer 40 formed thereon is retained on the dicing tape 300 again with the side on which the cut portion is formed (light emitting element 11 side) up (FIG. 5E). Then, the dicing tape 300 is expanded. Thus, the LED wafer 10 is split from the cut portion as an origin, to thereby obtain the LEDs 50 singulated into small element pieces (FIG. 5F).

In an embodiment of the present invention illustrated in FIGS. 6A to 6F, the LED wafer with the protective sheet, which has been subjected to the back-grinding step, is retained on the dicing tape 300 with the protective sheet 20 side down (FIG. 6A). Subsequently, the LED wafer 10 is half-cut from the substrate 12 side (FIG. 6B). Subsequently, the LED wafer 10 having the cut portion formed therein as described above is subjected to the reflective layer forming step. That is, the LED wafer 10 is placed on the table 200 with the light emitting element 11 side (protective sheet 20 side) down, and the reflective layer 40 is formed on the substrate 12 side of the LED wafer 10 (FIG. 6C). The LED wafer 10 may be placed on the table 200 under a state in which the dicing tape 300 is still adhering on the outer side of the protective sheet 20, or may be placed on the table 200 after the dicing tape 300 is peeled off (in the illustrated example, the LED wafer 10 is placed after the dicing tape 300 is peeled off). Subsequently, the LED wafer 10 having the reflective layer 40 formed thereon is retained on the dicing tape 300 again with the protective sheet 20 side up (FIG. 6D), and then the protective sheet 20 is peeled off (FIG. 6E). Then, the dicing tape 300 is expanded. Thus, the LED wafer 10 is split from the cut portion as an origin, to thereby obtain the LEDs 50 singulated into small element pieces (FIG. 6F).

Regarding the LED wafer with the protective sheet, which is obtained through the above-mentioned second embodiment (embodiment illustrated in FIGS. 3A to 3D), in the dicing step, the dicing tape may be attached with the protective sheet side up, and after that, the protective sheet may be peeled off so as to form the cut portion and split the LED wafer. Further, the LED wafer with the protective sheet, which is obtained through the above-mentioned second embodiment, may be subjected to the dicing step after the protective sheet is peeled off. At this time, the dicing tape may be attached to any one of the light emitting element side and the substrate side of the LED wafer.

The LED wafer with the protective sheet, which is obtained through the above-mentioned second embodiment, may be subjected to the reflective layer forming step after the protective sheet is peeled off. The reflective layer forming step may be performed any one of prior to and after the formation of the cut portion, similarly to that performed for the LED wafer obtained through the first embodiment.

1. A method of manufacturing an LED, the method comprising:
back-grinding a substrate of an LED wafer including a light emitting element and the substrate; and
attaching a protective sheet to the LED wafer one of prior to the back-grinding and after grinding the substrate in the back-grinding.

2. A method of manufacturing an LED according to claim 1, wherein the attaching a protective sheet comprises, prior to the back-grinding, attaching the protective sheet on an outer side of the light emitting element of the LED wafer.

3. A method of manufacturing an LED according to claim 2,
wherein the grinding the substrate in the back-grinding is carried out by attaching the protective sheet to a table via a pressure-sensitive adhesive wax to fix the LED wafer to the table, and
wherein the method further comprises, after the grinding the substrate, taking off the protective sheet to remove, from the LED wafer, the pressure-sensitive adhesive wax adhering on the LED wafer with the protective sheet, which has been released from the table.

4. A method of manufacturing an LED according to claim 1, wherein the attaching a protective sheet comprises, after the grinding the substrate in the back-grinding, attaching the protective sheet on an outer side of the substrate of the LED wafer.

5. A method of manufacturing an LED according to claim 1, further comprising, after the back-grinding, forming a reflective layer.
